(19) United States
(12) Patent Application Publication
(10) Pub. No.: US 2006/0270088 A1
(43) Pub. Date: Nov. 30, 2006

(54) Micromechanical component and method for production thereof

(76) Inventors: Frank Fischer, Gomaringen (DE); Markus Lutz, Los Altos, CA (US)

Correspondence Address: KENYON & KENYON LLP, ONE BROADWAY, NEW YORK, NY, 10004, US

(21) Appl. No.: 10/543,441

(22) PCT Filed: Sep. 23, 2003
(86) PCT No.: PCT/DE03/03151

§ 371 Date: May 4, 2006

(30) Foreign Application Priority Data
Jan. 24, 2003 (DE) 10302676.2

(51) Int. Cl. H01L 21/00; H01L 29/84

(52) U.S. Cl. 438/48; 257/415

(57) ABSTRACT

An epitaxial layer having monocrystalline and polycrystalline silicon grown side by side is deposited on a substrate, a region being exposed as a vertically movable polycrystalline diaphragm, especially for a pressure sensor, by etching. The poly/mono transition regions on both sides of the diaphragm each nave an oblique profile such that the monocrystalline silicon extends into the diaphragm region in the form of an overhang above the polycrystalline silicon. Piezo elements are implanted in the overhang.

### FIELD OF THE INVENTION

The present invention relates to a micromechanical component, especially a pressure sensor, made up of a silicon substrate having deposited thereon an epitaxial layer having monocrystalline and polycrystalline silicon grown simultaneously side by side, a region of the epitaxial layer being exposed as a vertically movable diaphragm by an etching process, and the epitaxial layer being made up, in a region approximately corresponding to the diaphragm region, of polycrystalline silicon that changes to monocrystalline silicon on both sides of the diaphragm, thereby forming transition regions.

### BACKGROUND INFORMATION

German Published Patent Application No. 43 18 466 proposes applying a silicon oxide layer as a sacrificial layer to the silicon substrate and then applying an epitaxial layer, the latter growing in polycrystalline form above the sacrificial layer and, laterally thereof, on the substrate, in monocrystalline form.

Although capable of application to any micromechanical components having such epitaxial diaphragm structures, the present invention and the problem underlying it will be explained with reference to a micromechanical pressure sensor having piezoresistive resistance elements which may be fabricated using silicon surface micromachining technology.

### SUMMARY OF THE INVENTION

Micromechanical pressure sensors in which piezoresistive resistance elements are disposed on a silicon diaphragm so that their electrical resistance changes as a result of deformation of the diaphragm are known per se. In the case of piezoresistive recording of measurements, however, unlike micromechanical pressure sensors having a capacitive measurement principle, for example, the fundamental prerequisite for low-noise measurements is that the resistance elements be integrated in monocrystalline silicon.

That prerequisite has not hitherto been compatible with generic components, in which the diaphragm is comprised of polycrystalline silicon.

It is otherwise known from German Published Patent Application No. 195 26 691, in connection with a method for the production of sensors which includes simultaneous epitaxial deposition of polycrystalline and monocrystalline silicon, that the growth of the epitaxial layer on a silicon substrate having a sacrificial layer applied to it takes place in such a manner that the polycrystalline region additionally extends slightly, by an oblique profile, to both sides of the sacrificial layer, that is to say, beyond the diaphragm region. In view of this, it appears from the outset even more certain that the epitaxial diaphragm is not amenable to piezoresistive evaluation.

The problem underlying the present invention is to develop a micromechanical component of the kind mentioned in the introduction and to provide a corresponding production method in such a manner that the component becomes amenable to piezoresistive evaluation.

That problem is solved in a micromechanical component of the kind mentioned in the introduction by virtue of the fact that the transition regions from polycrystalline to monocrystalline silicon each have an oblique profile such that the monocrystalline silicon extends into the diaphragm region in the form an overhang above the polycrystalline silicon.

The idea underlying the present invention is to grow the epitaxial layer on the basis of a topography in which, as the reverse of previous topographies, the region of the sacrificial layer is sunken with respect to the monocrystalline lateral silicon regions, so that, in a transition region situated in the periphery of the diaphragm region, the silicon growing in monocrystalline form grows laterally in the manner of an overhang over the polycrystalline silicon growing on the sacrificial layer. Owing to the overhangs which extend into the periphery, the diaphragm, the body of which is comprised, as before, of epitaxially grown polycrystalline silicon, therefore has monocrystalline subregions, namely the overhangs, that are advantageously accessible from the upper side of the diaphragm.

In an advantageous development of the invention, therefore, the component may be constructed as a sensor and means may be provided for evaluating the movement of the diaphragm, at least one measuring element being disposed on the upper side of the diaphragm, in the region of the monocrystalline overhang, for the purpose of measuring the movement.

Consequently, implementation of the measuring elements on or in the diaphragm is no longer restricted to polycrystalline silicon. According to an especially preferred development, it is possible, in particular, for the sensor to be provided as a pressure sensor and for the evaluation of the deformation of the diaphragm to be performed piezoresistively, at least one piezoresistive resistance element being implanted in the region of the monocrystalline overhang.

The invention furthermore makes it possible for one or more electronic circuit elements and/or wiring elements to be integrated in the monocrystalline silicon of the epitaxial layer, preferably outside the diaphragm region.

A method for the production of a micromechanical component according to the invention provides that
a sacrificial layer preferably comprised of silicon oxide is deposited on the silicon substrate and is patterned appropriately to the subsequent diaphragm region,
in an epitaxy system, monocrystalline silicon is selectively grown on the silicon substrate, on both sides of the sacrificial layer, those monocrystalline lateral regions being grown to a height that is greater than the thickness of the sacrificial layer,
an epitaxial layer of silicon is then deposited, which grows in polycrystalline form above the sacrificial layer and in monocrystalline form above the lateral regions which have grown in monocrystalline form,
the developing monocrystalline silicon grows obliquely from the lateral regions to form an overhang above the polycrystalline silicon developing from the sunken subsequent diaphragm region,
and, to expose a silicon diaphragm, the sacrificial layer beneath the epitaxial layer is removed by an etching process.

By the first step of that two-stage epitaxy process it is accordingly possible to achieve the above-mentioned reversing of the topography, which then leads, in the second epitaxy step, to the desired monocrystalline overhangs.

An especially advantageous embodiment of the method is one in which a poly-starter layer is applied to the sacrificial layer before production of the epitaxial layer, the monocrystalline lateral regions being selectively grown to a height that is greater than the thickness made up of the thickness of the sacrificial layer and the thickness of the poly-starter layer.

That embodiment may be implemented in an especially simple manner by depositing the poly-starter layer on the silicon substrate and then removing the poly-starter layer on the monocrystalline lateral regions by a CMP step.

With regard to process engineering it is advantageous, in accordance with another development of the method, to produce the epitaxial layer without a poly-starter layer that has to be applied separately, either merely by changing the process parameters from a selective to a nonselective regime or by the production of an in situ poly-starter layer, which is possible in the nonselective regime.

The method according to the present invention may advantageously be implemented using purely surface micromachining process steps. Only two masks are required: at the beginning of the process for the purpose of patterning the sacrificial layer and later for the production of the etching apertures necessary for exposing the diaphragm. Owing to the prior production of the micromechanical structures, the method may readily be combined with the customary back end CMOS processes. The independence of the micromachining processes and the CMOS processes prevents the method from being undesirably bound to specific CMOS processes. The thickness of the diaphragm may be precisely controlled or set. The epitaxy system may be operated in a wide pressure range.

### BRIEF DESCRIPTION OF THE DRAWINGS

FIG. 1 shows a first illustration of a section through a component according to the present invention in various phases of production.

FIG. 2 shows a second illustration of a section through a component according to the present invention in various phases of production.

FIG. 3 shows a third illustration of a section through a component according to the present invention in various phases of production.

FIG. 4 shows a fourth illustration of a section through a component according to the present invention in various phases of production.

FIG. 5 shows a fifth illustration of a section through a component according to the present invention in various phases of production.

FIG. 6 shows a sixth illustration of a section through a component according to the present invention in various phases of production.

FIG. 7 shows a seventh illustration of a section through a component according to the present invention in various phases of production.

### DETAILED DESCRIPTION

FIG. 1 shows a silicon substrate 1 on which a sacrificial layer 2 comprised, for example, of silicon dioxide has already been deposited and patterned in a manner known per se.

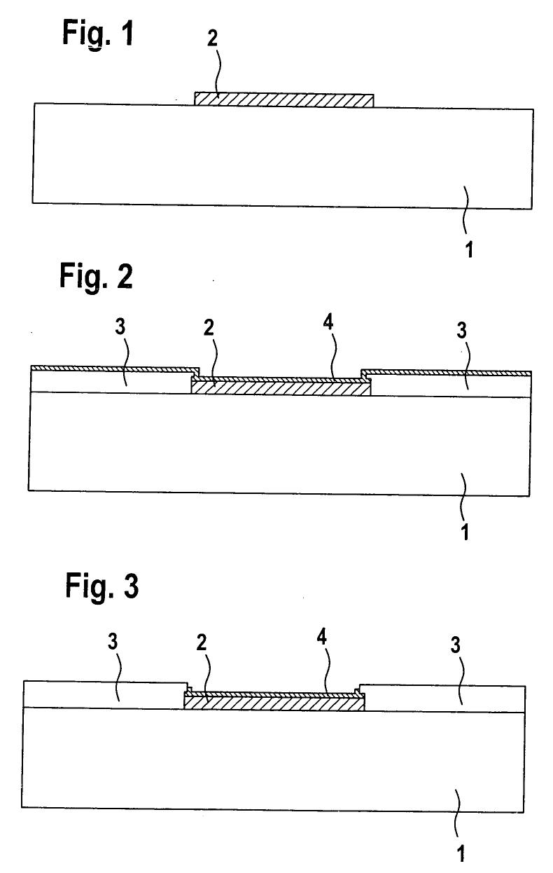

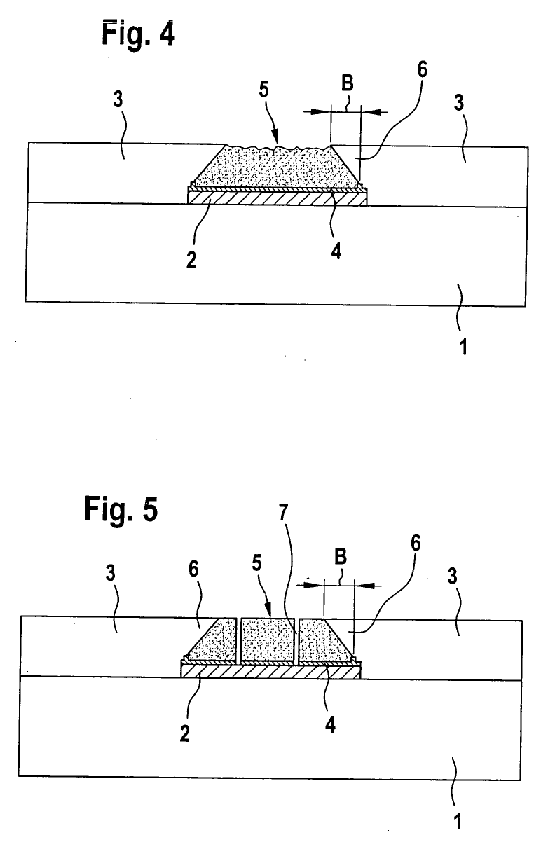

FIG. 2 shows additional monocrystalline lateral regions 3 which have been grown on both sides of sacrificial layer 2 by selective epitaxy, that is to say, above substrate 1. Selective epitaxy is a process known per se in which no silicon grows on sacrificial layer 2. The slight projection of lateral regions 3 above sacrificial layer 2, which is indicated in FIG. 2, comes about as a result of lateral silicon growth at the further developing lateral regions 3 as soon as they have attained the thickness of sacrificial layer 2. That projection is not causative in the epitaxial growth with an oblique profile illustrated in FIG. 4 and is also based on a different development mechanism from that of the oblique profile. Apart from that, if desirable for other reasons, it is possible for the extent of projection to be set in a relatively wide range by the process parameters.

The important step shown in FIG. 2 is the reversing of the topography as compared with FIG. 1: the height of lateral regions 3 is greater than the thickness of sacrificial layer 2, and therefore the latter is in a sunken position (recess) relative to monocrystalline lateral regions 3. Even when, as illustrated in FIG. 2, a polycrystalline starter layer 4, which is preferably deposited by LPCVD, is produced above sacrificial layer 2 and lateral regions 3, that topography is to be retained, i.e. the height of lateral regions 3 is in that case also greater than the combined thicknesses of sacrificial layer 2 and poly-starter layer 4 in diaphragm region 5 and 6.

FIG. 3 shows the stage of the method after removal of regions of poly-starter layer 4 above monocrystalline lateral regions 3, which regions of poly-starter layer 4 are preferably eliminated by a CMP (chemical mechanical polishing) process.

Patterning of poly-starter layer 4 is accordingly performed, as described in connection with FIG. 3, preferably in a self-centered manner; it is equally possible, however, for poly-starter layer 4 to be patterned using an additional mask. In the latter case, the polycrystalline region of starter layer 4 above sacrificial layer 2 may be protected by a protective layer (not shown) in such a manner that an oxide or nitride protective layer is applied and is removed over lateral regions 3 and a narrow, outermost border in the peripheral region of sacrificial layer 2 by a photolithography step with subsequent etching. Thereafter, poly-starter layer 4 may be selectively removed above lateral regions 3 by etching. The protective layer itself (which may also be used if appropriate before a CMP step) is then removed again.

FIG. 4 shows the next stage of the method, after the in situ epitaxial growth of silicon which (still) grows in monocrystalline form in lateral regions 3, but which grows as polycrystalline region 5 above poly-starter layer 4. The growth of monocrystalline regions 3 and of polycrystalline region 5 takes place simultaneously and substantially side by side and at similar growth rates. Starting at the higher level of lateral regions 3, the monocrystalline silicon grows laterally and vertically, with the result that, owing to poly-starter layer 4 being sunken, lateral growth of monocrystalline region 3 over polycrystalline region 5 occurs. This results in the formation of an overhang 6 on each side, that is to say, in a monocrystalline sub-region in the periphery of the subsequent diaphragm region 5 and 6. The transition regions between monocrystalline and polycrystalline silicon are, therefore, quasi integrated in diaphragm region 5 and 6 instead of being disposed in lateral regions 3 as in the case of the known component with an epitaxial diaphragm.

The height of the “recess” is responsible for the width “B”, see FIG. 4, of overhang 6. In the case of a high step, e.g. of 4 μm, overhang 6 is up to 12 μm at a thickness of epitaxial layer 3 and 5 of about 10 μm.

FIG. 5 shows the stage of the method after a further CMP step has been carried out to obtain a planar surface and after production of etching apertures 7 which, for example, may have a cross-section of 5×5 μm and are formed between what are initially portions 8 of diaphragm 5 and 6.

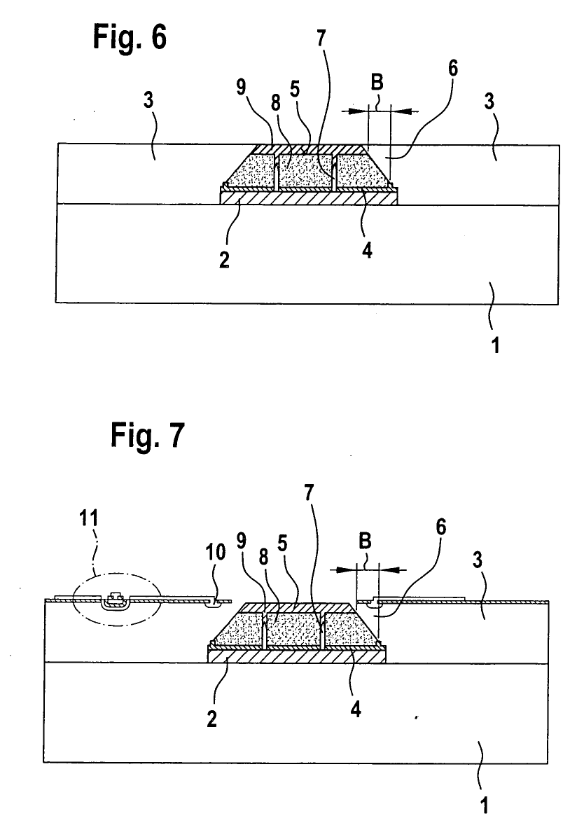

FIG. 6 shows the stage of the method in which diaphragm 5 and 6 has been vertically exposed by a sacrificial layer etching process, for example using HF vapor or XeF₂ (for etching a sacrificial layer of polysilicon or SiGe, it is necessary for a thin passivation layer, e.g. oxide or nitride, to be deposited beforehand, which then has to be removed from etching apertures 7 again). In place of sacrificial layer 2, there is then a cavity beneath diaphragm 5 and 6.

It is also possible to see in FIG. 6 a refilling 9 of etching apertures 7, preferably by monocrystalline and polycrystalline epitaxial silicon growth, in order to maintain planarity. It is also possible, however, for a planarizing oxide layer to be applied.

It is then possible, as illustrated in FIG. 7, for piezoresistive resistance elements 10 to be implanted without any difficulty in monocrystalline overhang 6. Thereafter, CMOS circuit structures 11 may be produced, also in the monocrystalline silicon but typically outside diaphragm 5 and 6.

The Si epitaxy described above for the production of monocrystalline lateral regions 3 may be carried out in a strictly selective regime by delivering chlorine to the upper side of silicon substrate 1 in a manner known per se. The delivery of chlorine to establish the selectivity of the epitaxy process is advantageously implemented by supplying HCl gas. It should be noted that, in the case of selective process management, it is possible for epitaxial silicon to be grown in a reproducible manner only on silicon, that is to say, not on the bare (oxide) sacrificial layer 2. In order to ensure this in the production of epitaxial layer 3 and 5, as described hereinbefore separate production of a poly-starter layer 4 on sacrificial layer 2 is preferred.

Alternatively, however, there is also the possibility of establishing, after the selective regime, that is, after completion of monocrystalline lateral regions 3, a non-selective regime by reducing chlorine delivery, in which non-selective regime epitaxial layer 3 and 5 also grows above sacrificial layer 2.

Since that is generally associated with a deterioration in quality in the epitaxial layer both in the monocrystalline and in the polycrystalline region 3 and 5 respectively, in that case, in an especially preferred form of process management, the change to the non-selective regime takes place (only) until a poly-starter layer 4 has been produced in situ by polycrystalline seeding of sacrificial layer 2, and further production of epitaxial layer 3 and 5 is carried out after changing to the selective regime again, so that polycrystalline silicon is grown above the in situ poly-starter layer 4 and monocrystalline silicon is grown above the lateral regions, side by side, in one method step.

Although the present invention has been described above with reference to one preferred exemplary embodiment, it is not limited thereto but may be modified in a variety of ways.

For example, it is possible for further method steps known per se which are not shown in the Figures to be provided in order, in particular, to obtain further circuit and/or wiring structures.

Finally, a pressure sensor featuring piezoresistive recording of measurements was shown in the above exemplary embodiment, but the invention is also capable of application to other sensors and to epitaxial diaphragm structures used in a different way, in which measuring elements 10 are not piezoresistive resistance elements or are not present at all.

1.-11. (canceled)

12. A micromechanical component, comprising:
a silicon substrate having deposited thereon an epitaxial layer provided with monocrystalline silicon and polycrystalline silicon grown side by side, wherein:
a diaphragm region of the epitaxial layer is exposed as a vertically movable diaphragm via etching,
the epitaxial layer includes, in another region approximately corresponding to the diaphragm region, a polycrystalline silicon that changes to monocrystalline silicon on both sides of the diaphragm, thereby forming transition regions, and
the transition regions from polycrystalline silicon to monocrystalline silicon each have an oblique profile such that the monocrystalline silicon extends into the diaphragm region as a monocrystalline overhang above the polycrystalline silicon.

13. The micromechanical component as recited in claim 12, wherein:
the micromechanical component is a pressure sensor.

14. The micromechanical component as recited in claim 12, further comprising:
an arrangement for evaluating a movement of the diaphragm; and
at least one measuring element disposed on an upper side of the diaphragm, in a region of the monocrystalline overhang, in order to measure the movement, wherein:
the micromechanical component is constructed as a sensor.

15. The micromechanical component as recited in claim 14, further comprising:
at least one piezoresistive element implanted in the region of the monocrystalline overhang, wherein:
the sensor includes a pressure sensor, and
an evaluation of a deformation of the diaphragm is performed piezoresistively.

16. The micromechanical component as recited in claim 12, further comprising:
at least one of at least one electronic circuit element and at least one wiring element integrated in the monocrystalline silicon of the epitaxial layer outside the diaphragm region.

17. A method for producing a micromechanical component, comprising:
depositing a sacrificial layer on a silicon substrate;
patterning the sacrificial layer appropriately to a subsequent diaphragm region;
in an epitaxy system, selectively growing monocrystalline silicon on the silicon substrate, on both sides of the sacrificial layer, wherein monocrystalline lateral regions are grown to a height that is greater than a thickness of the sacrificial layer;
subsequent to the selectively growing, depositing an epitaxial layer of silicon and causing the epitaxial layer to grow in polycrystalline form above the sacrificial layer and in monocrystalline form above the lateral regions grown in monocrystalline form, wherein:
the monocrystalline silicon grows obliquely from the lateral regions
to form an overhang above the polycrystalline silicon developing from the subsequent diaphragm region that is sunken; and
in order to expose a silicon diaphragm, removing the sacrificial layer beneath the epitaxial layer by an etching operation.

18. The method as recited in claim 17, wherein:
the sacrificial layer includes silicon oxide.

19. The method as recited in claim 18, further comprising:
applying a poly-starter layer to the sacrificial layer before production of the epitaxial layer, wherein:
the monocrystalline lateral regions are selectively grown to a height that is greater than a thickness made up of the thickness of the sacrificial layer and a thickness of the poly-starter layer.

20. The method as recited in claim 19, further comprising:
depositing the poly-starter layer on the silicon substrate; and
subsequent to the depositing of the poly-starter layer, removing the poly-starter layer on the monocrystalline lateral regions by a CMP operation.

21. The method as recited in claim 17, further comprising:
applying an Si epitaxy to produce the monocrystalline lateral regions in a strictly selective regime by delivering chlorine to an upper side of the silicon substrate.

22. The method as recited in claim 21, further comprising:
after the selective regime, establishing a non-selective regime by reducing the chlorine delivery, the epitaxial layer growing above the sacrificial layer in the non-selective regime.

23. The method as recited in claim 22, wherein:
a change to the non-selective regime takes place until a poly-starter layer has been produced in situ by polycrystalline seeding of the sacrificial layer, and
further production of the epitaxial layer is carried out after switching to the selective regime again, so that polycrystalline silicon is grown above the in situ poly-starter layer, and monocrystalline silicon is grown above the monocrystalline lateral regions, side by side, in one process step.

24. A method as recited in claim 21, wherein the delivery of chlorine to establish the selectivity of the epitaxy process is implemented by supplying HCl gas.
